(19) United States
(12) Patent Application Publication
(10) Pub. No.: US 2013/0136269 A1
(43) Pub. Date: May 30, 2013

(54) ACTIVE VIBRATION NOISE CONTROL APPARATUS

(71) Applicant: HONDA MOTOR CO., LTD., Tokyo (JP)

(72) Inventors: Kosuke SAKAMOTO, Utsunomiya-shi (JP); Toshio INOUE, Tochigi-ken (JP)

(73) Assignee: HONDA MOTOR CO., LTD., Tokyo (JP)

(21) Appl. No.: 13/686,590

(22) Filed: Nov. 27, 2012

(30) Foreign Application Priority Data
Nov. 29, 2011 (JP) 2011-259687

(51) Int. Cl. H03B 29/00

(52) U.S. Cl. CPC H03B 29/00
USPC 381/71.4

(57) ABSTRACT

An active vibration noise control apparatus cancels out vibration noise generated in the passenger compartment of a vehicle when the vehicle is traveling, by outputting canceling vibration noise. The active vibration noise control apparatus includes a frequency switcher. The frequency switcher calculates a phase angle change between a phase angle in a complex space of a filter coefficient of an adaptive notch filter and a previous phase angle calculated when the filter coefficient is updated previously, and changes a target frequency of a reference signal depending on the calculated phase angle change.

### CROSS-REFERENCE TO RELATED APPLICATION

This application is based upon and claims the benefit of priority from Japanese Patent Application No. 2011-259687 filed on Nov. 29, 2011, the contents of which are incorporated herein by reference.

### BACKGROUND OF THE INVENTION

1. Field of the Invention

The present invention relates to an active vibration noise control apparatus for canceling out vibration noise generated in the passenger compartment of a vehicle when the vehicle is traveling, by outputting canceling vibration noise.

2. Description of the Related Art

When a vehicle is traveling, vibrations of the road wheels are transmitted through the suspensions to the vehicle body, thereby generating road noise (including vibrations and noise, hereinafter collectively referred to as “vibration noise”) in the passenger compartment. There have been proposed various active vibration noise control apparatus which output, from a speaker, canceling vibration noise that is in opposite phase with the generated vibration noise for thereby canceling out the vibration noise.

For example, Japanese Laid-Open Patent Publication No. 2009-045954 (hereinafter referred to as JP2009-045954A) discloses an active vibration noise control apparatus which extracts a signal component having a certain frequency, using an adaptive notch filter, from an error signal that is detected by a microphone placed in the passenger component of a vehicle, and adjusts the amplitude and phase of a control signal that is generated based on the extracted signal component. The disclosed active vibration noise control apparatus can reduce an amount of arithmetic processing significantly, and hence can be constructed at a low cost.

### SUMMARY OF THE INVENTION

It is an object of the present invention to provide an active vibration noise control apparatus which is capable of canceling vibration noise having changing frequency characteristics, in response to the change in the frequency characteristics, the active vibration noise control apparatus being related to the technical concept disclosed in JP2009-045954A.

According to the present invention, there is provided an active vibration noise control apparatus comprising a vibration noise canceller for outputting canceling vibration noise based on a canceling signal to cancel out vibration noise, an error signal detector for detecting residual vibration noise due to an interference between the vibration noise and the canceling vibration noise as an error signal, and an active vibration noise controller for generating the canceling signal in response to the error signal input thereto, wherein the active vibration noise controller comprises a reference signal generator for generating a reference signal having a frequency, an adaptive notch filter, which has a filter coefficient defined in a complex space, for outputting a control signal for use in generating the canceling signal in response to the reference signal input thereto, an amplitude/phase adjuster for storing therein an amplitude or phase adjusting value depending on the frequency of the reference signal, and generating the canceling signal by adjusting an amplitude or phase of the control signal with the amplitude or phase adjusting value, a corrective error signal generator for generating a corrective error signal by subtracting the control signal from the error signal, a filter coefficient updater for sequentially updating the filter coefficient so as to minimize the corrective error signal based on the reference signal and the corrective error signal, and a frequency switcher for calculating a phase angle change between a phase angle in the complex space of the filter coefficient and a phase angle calculated when the filter coefficient is updated previously, and changing the frequency of the reference signal depending on the calculated phase angle change.

Since the active vibration noise control apparatus includes the frequency switcher which calculates a phase angle change between the phase angle in the complex space of the filter coefficient of the adaptive notch filter and a phase angle calculated when the filter coefficient is updated previously, and changes the frequency of the reference signal depending on the calculated phase angle change, a change in the phase angle in the complex space of the filter coefficient can be monitored sequentially, and the tendency of a change in the frequency characteristics can simply and accurately be grasped from the phase angle change. Consequently, the vibration noise with changing frequency characteristics can be canceled out in response to the change in the frequency characteristics.

The frequency switcher should preferably calculate a change in the frequency based on a sampling period of the error signal and the phase angle change, and maintain the frequency of the reference signal if the change in the frequency is lower than a lower limit threshold value. If the change in the frequency is lower than the lower limit threshold value, then different type of noise due to frequency changing is prevented from occurring.

The frequency switcher should preferably maintain the frequency of the reference signal if the change in the frequency is higher than an upper limit threshold value which is greater than the lower limit threshold value. If the change in the frequency is higher than the higher limit threshold value which is greater than the lower limit threshold value, then different type of noise due to excessive control is prevented from occurring.

The active vibration noise control apparatus should preferably further comprise an amplitude/phase switcher for changing the amplitude or phase adjusting value which is stored in the amplitude/phase adjuster, in response to change of the frequency of the reference signal by the frequency switcher. The changing of the frequency of the reference signal can thus immediately be reflected in the canceling signal, thereby for better control following capability.

As described above, the active vibration noise control apparatus according to the present invention includes the frequency switcher which calculates a phase angle change between the phase angle in the complex space of the filter coefficient of the adaptive notch filter and a phase angle calculated when the filter coefficient is updated previously, and changes the frequency of the reference signal depending on the calculated phase angle change. Consequently, a change in the phase angle in the complex space of the filter coefficient can be monitored sequentially, and the tendency of a change in the frequency characteristics can simply and accurately be grasped from the phase angle change. Therefore, the vibration noise with changing frequency characteristics can be canceled out in response to the change in the frequency characteristics.

The above and other objects, features, and advantages of the present invention will become more apparent from the following description when taken in conjunction with the accompanying drawings in which a preferred embodiment of the present invention is shown by way of illustrative example.

### BRIEF DESCRIPTION OF THE DRAWINGS

FIG. 1 is a block diagram showing a basic and general arrangement of an active vibration noise control (ANC) apparatus incorporated in a vehicle according to an embodiment of the present invention;

FIG. 2 is a flowchart of an operation sequence of the ANC apparatus shown in FIG. 1;

FIG. 3 is a detailed block diagram of an active vibration noise controller shown in FIG. 1;

FIG. 4 is a detailed flowchart of a process of updating a target frequency in step S6 shown in FIG. 2;

FIG. 5 is a diagram illustrative of a process of calculating a phase angle change in a complex space of a filter coefficient;

FIG. 6A is a spectral diagram of an error signal prior to the execution of an ANC process;

FIG. 6B is a diagram showing the frequency characteristics of an SAN (Single Adaptive Notch) bandpass filter suitable for the error signal shown in FIG. 6A;

FIG. 6C is a diagram showing the frequency characteristics of an adaptive notch filter, which correspond to the frequency characteristics of the SAN bandpass filter shown in FIG. 6B;

FIG. 7A is a spectral diagram of an error signal the frequency characteristics of which have changed from those shown in FIG. 6A;

FIG. 7B is a diagram showing the frequency characteristics of a SAN bandpass filter suitable for an error signal shown in FIG. 7A;

FIG. 8A is a diagram showing the frequency characteristics of an adaptive notch filter in a case where a frequency switching process is not carried out;

FIG. 8B is a diagram showing the frequency characteristics of a sensitivity function of the ANC apparatus in a case where the frequency switching process is not carried out;

FIG. 8C is a spectral diagram of an error signal after the ANC process is carried out in a case where the frequency switching process is not carried out;

FIG. 9A is a diagram showing the frequency characteristics of the adaptive notch filter in a case where the frequency switching process is carried out;

FIG. 9B is a diagram showing the frequency characteristics of a sensitivity function of the ANC apparatus in a case where the frequency switching process is carried out; and

FIG. 9C is a spectral diagram of an error signal after the ANC process is carried out in a case where the frequency switching process is carried out.

### DESCRIPTION OF THE PREFERRED EMBODIMENTS

A preferred embodiment of an active vibration noise control apparatus according to the present invention will be described below with reference to the accompanying drawings.

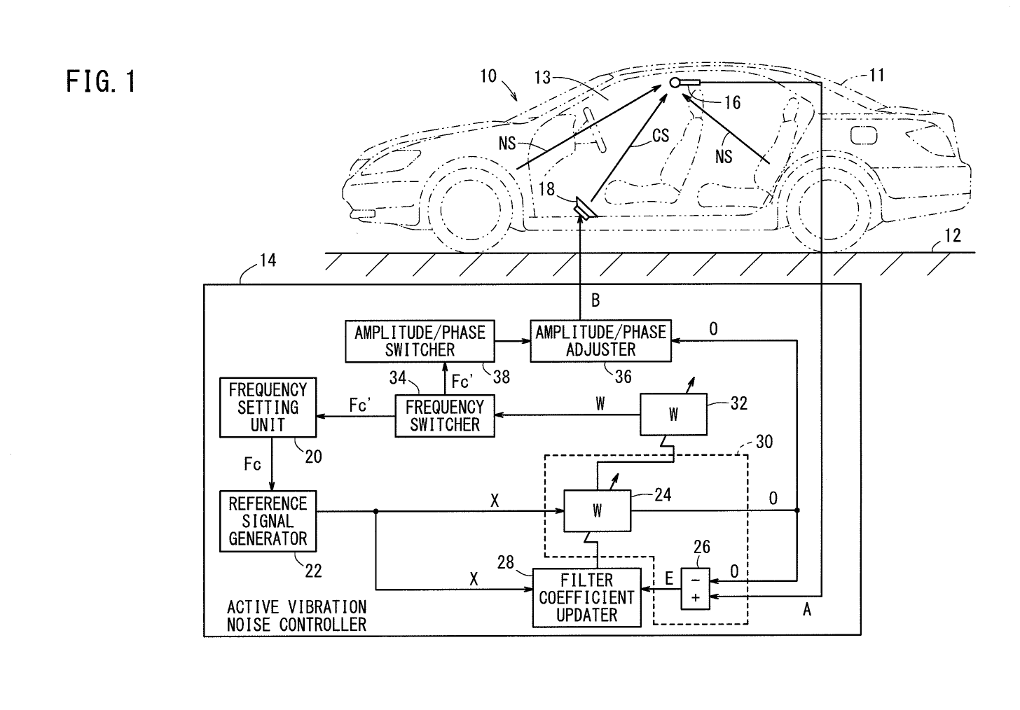

As shown in FIG. 1, a vehicle 11 includes the active vibration noise control apparatus (ANC apparatus) 10. The ANC apparatus 10 includes an active vibration noise controller 14 (active vibration noise controller), a microphone 16 (error signal detector), and a speaker 18 (vibration noise canceller).

To the microphone 16, various sounds that are generated inside and outside the vehicle 11 are input. The sounds that are input to the microphone 16 include vibration noise NS caused by vibrations of the road wheels of the vehicle 11 that are transmitted from a road 12, and canceling vibration noise CS for canceling the vibration noise NS. The microphone 16 detects residual vibration noise due to an interference between the vibration noise NS and the canceling vibration noise CS as an input signal (hereinafter referred to as an error signal A) to be applied to the active vibration noise controller 14. In FIG. 1, the microphone 16 is disposed in an upper portion of a passenger compartment 13 of the vehicle 11, or specifically near a sound receiving point of a passenger, not shown.

The term “vibration noise” used herein refers to an overall range of elastic waves that are propagated through elastic bodies. In other words, vibration noise is not limited to a narrow sense of audible sounds, i.e., an elastic wave having an audible frequency and propagated through air. If vibrations are to be detected, a vibration sensor or the like may be used instead of the microphone 16.

The speaker 18 outputs canceling vibration noise CS based on an output signal (hereinafter referred to as a canceling signal B) from the active vibration noise controller 14. Specifically, the speaker 18 outputs canceling vibration noise CS that is in opposite phase with vibration noise NS including a certain frequency as a main component, for suppressing the generation of the vibration noise NS by way of an interference between waves. In the present embodiment, the speaker 18 is disposed near a kick panel around a seat in the passenger compartment 13.

The active vibration noise controller 14 performs an active vibration noise control process (hereinafter referred to as “ANC process”) by carrying out a predetermined signal processing process on the error signal A input thereto to generate a canceling signal B, and supplying the canceling signal B to the speaker 18, which outputs canceling vibration noise CS to adaptively cancel out the vibration noise NS. The active vibration noise controller 14 comprises a microcomputer, a DSP (Digital Signal Processor), etc. The active vibration noise controller 14 can perform various processes by executing programs stored in a memory such as a ROM by the CPU (Central Processing Unit) of the microcomputer based on various input signals.

The active vibration noise controller 14 includes a frequency setting unit 20 for setting a frequency (target frequency Fc) to be processed by the ANC process from within a given frequency range, a reference signal generator 22 (reference signal generator) for generating a reference signal X having as its main component the target frequency Fc set by the frequency setting unit 20, and an adaptive notch filter 24 for performing a SAN (Single Adaptive Notch) filtering process on the reference signal X generated by the reference signal generator 22 thereby to generate a control signal O.

The active vibration noise controller 14 also includes a subtractor 26 (corrective error signal generator) for subtracting the control signal O output from the adaptive notch filter 24 from the error signal A detected by the microphone 16 to generate a corrective error signal E, and a filter coefficient updater 28 (filter coefficient updater) for sequentially updating a filter coefficient W of the adaptive notch filter 24 so as to minimize the corrective error signal E based on the corrective error signal E output from the subtractor 26.

The adaptive notch filter 24 and the subtractor 26 are combined into a SAN bandpass filter 30. The corrective error signal E corresponds to a signal obtained by removing frequency components within a certain range around the target frequency Fc from among frequency components within a relatively wide range included in the error signal A.

The active vibration noise controller 14 further includes a filter coefficient holder 32 for holding the filter coefficient W of the adaptive notch filter 24 that is sequentially updated by the filter coefficient updater 28, a frequency switcher 34 (frequency switcher) for judging whether the target frequency Fc is to be updated or not or determining how much the target frequency Fc is to be updated (updating quantity), based on the filter coefficient W supplied from the filter coefficient holder 32, an amplitude/phase adjuster 36 for adjusting the amplitude or phase of the control signal O using an amplitude or phase adjusting value, and an amplitude/phase switcher 38 (amplitude/phase switcher) for changing the amplitude or phase adjusting value based on a target frequency Fc′ updated by the frequency switcher 34.

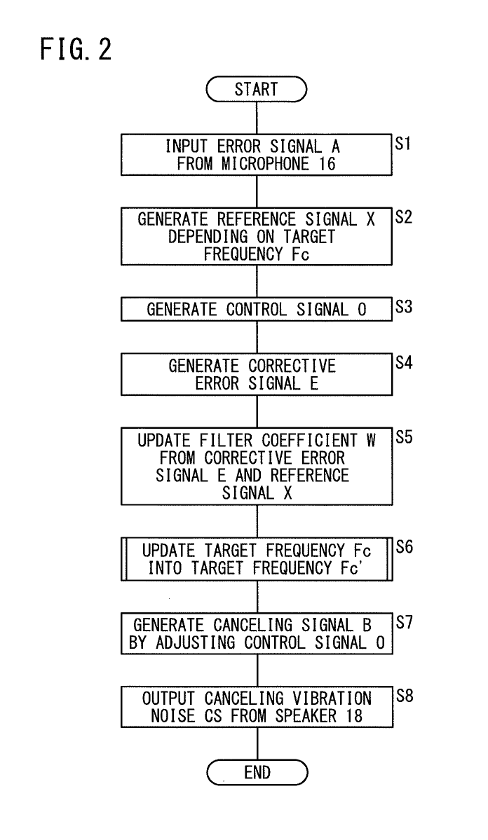

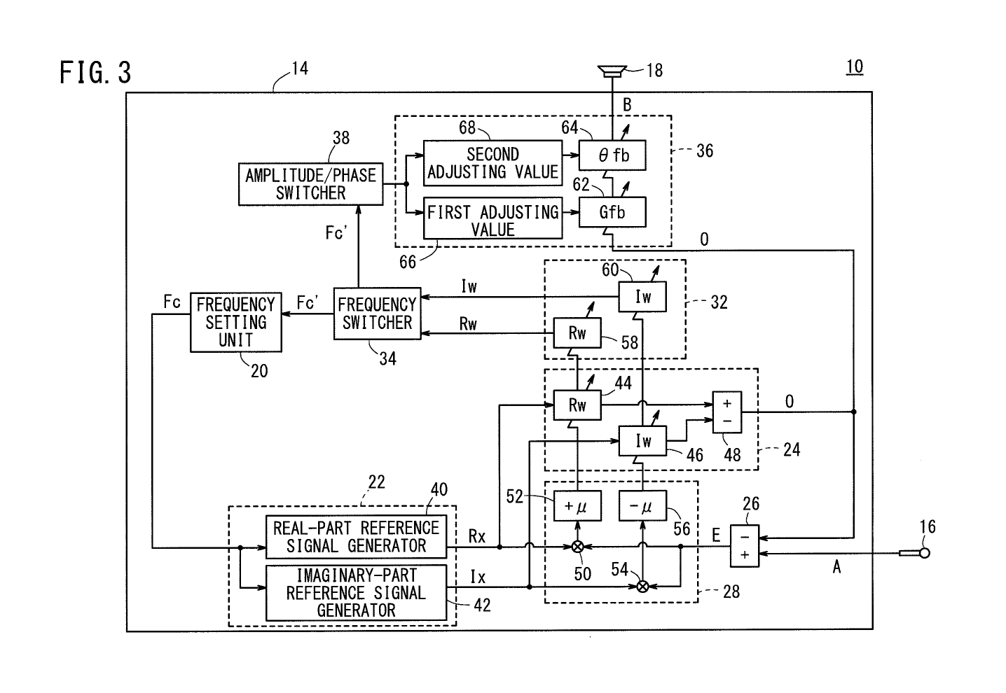

The ANC apparatus 10 according to the present embodiment is basically constructed as above. Each of the reference signal X and the filter coefficient W shown in FIG. 1 is defined in a complex space and has a real-part component and an imaginary-part component. Operation of the ANC apparatus 10 will be described in detail below with reference to a flowchart shown in FIG. 2 and a detailed block diagram shown in FIG. 3 with attention being paid to a signal processing sequence on the real-part component and the imaginary-part component.

In step S1 shown in FIG. 2, the microphone 16 detects residual vibration noise in the passenger compartment 13, and enters the detected signal as an error signal A. The error signal A represents not only the detected residual vibration noise, but also canceling vibration noise CS output from the speaker 18 for cancellation of vibration noise NS.

In step S2, the reference signal generator 22 generates a reference signal X which includes the target frequency Fc as a main component. Before the reference signal generator 22 generates the reference signal X, the frequency setting unit 20 sets a frequency, i.e., a target frequency Fc, to be processed by the ANC process. The frequency setting unit 20 may set a target frequency Fc in steps of 1-Hz within a control range from 50 Hz to 300 Hz. Thereafter, the frequency setting unit 20 controls the reference signal generator 22 to operate according to the target frequency Fc set thereby.

The reference signal generator 22 includes a real-part reference signal generator 40 for generating a real-part reference signal Rx {=cos(2πFc·t)} corresponding to the real part of the reference signal X, and an imaginary-part reference signal generator 42 for generating an imaginary-part reference signal Ix {=sin(2πFc·t)} corresponding to the imaginary part of the reference signal X. The reference signal X is expressed as a trigonometric function with respect to time (t), i.e., X(t)=exp(i2πFc·t) where i represents the imaginary unit.

In step S3, the adaptive notch filter 24 generates a control signal O to be supplied to the subtractor 26 and the amplitude/phase adjuster 36 based on the reference signal X from the reference signal generator 22. Specific configurational and operational details of the adaptive notch filter 24 will be described below.

The adaptive notch filter 24 includes a first filter 44 with a real-part filter coefficient Rw variably set therein, a second filter 46 with an imaginary-part filter coefficient Iw variably set therein, and a subtractor 48 for subtracting an output signal from the second filter 46 from an output signal from the first filter 44. The first filter 44 multiplies, by Rw, an amplitude component of the real-part reference signal Rx (cosine-wave signal) input from the real-part reference signal generator 40, and outputs the multiplied amplitude component to the subtractor 48. The second filter 46 multiplies, by Iw, an amplitude component of the imaginary-part reference signal Ix (sine-wave signal) input from the imaginary-part reference signal generator 42, and outputs the multiplied amplitude component to the subtractor 48. Thereafter, the subtractor 48 subtracts the output signal (=Iw·Ix) from the second filter 46, from the output signal (=Rw·Rx) from the first filter 44, thereby producing the difference as a control signal O (=Rw·Rx−Iw·Ix). Thus, the adaptive notch filter 24 outputs the control signal O.

In step S4, the subtractor 26 subtracts the control signal O (see step S3) output from the adaptive notch filter 24, from the error signal A (see step S1) output from the microphone 16, thereby generating a corrective error signal E. At this time, the SAN bandpass filter 30 (see FIG. 1) operates to generate a corrective error signal E obtained by removing only frequency components within a certain range around the target frequency Fc.

In step S5, the filter coefficient updater 28 updates the filter coefficient W of the adaptive notch filter 24. Specific configurational and operational details of the filter coefficient updater 28 will be described below.

The filter coefficient updater 28 includes a real-part multiplier 50 and a gain adjuster 52 which are used to update the real-part filter coefficient Rw corresponding to the real part of the filter coefficient W, and an imaginary-part multiplier 54 and a gain adjuster 56 which are used to update the imaginary-part filter coefficient Iw corresponding to the imaginary part of the filter coefficient W. According to the present embodiment, the filter coefficient updater 28 updates the filter coefficient W, i.e., the real-part filter coefficient Rw and the imaginary-part filter coefficient Iw, according to an LMS (Least Mean Square) algorithm. The updating algorithm is not limited to the LMS algorithm, but may be any of various other optimizing processes.

The real-part multiplier 50 multiplies the real-part reference signal Rx input thereto from the real-part reference signal generator 40 by the corrective error signal E input thereto from the subtractor 26, and outputs the multiplied signal to the gain adjuster 52. The gain adjuster 52 multiplies an amplitude component of the multiplied signal by a constant μ, and outputs the product as an updating quantity (=+μ·Rx·E) to the first filter 44. The constant μ corresponds to a step size parameter. The first filter 44 adds the updating quantity (=+μ·Rx·E) from the filter coefficient updater 28 to the real-part filter coefficient Rw at present, thereby producing a new real-part filter coefficient Rw. The real-part filter coefficient Rw is thus updated according to the following expression (1):

Rw←Rw+μ·Rx·E (1)

The imaginary-part multiplier 54 multiplies the imaginary-part reference signal Ix input thereto from the imaginary-part reference signal generator 42 by the corrective error signal E input thereto from the subtractor 26, and outputs the multiplied signal to the gain adjuster 56. The gain adjuster 56 multiplies an amplitude component of the multiplied signal by the constant μ, inverts the phase of the multiplied signal, i.e., adjust the phase by π, and outputs the inverted product as an updating quantity (=−μ·Ix·E) to the second filter 46. The second filter 46 adds the updating quantity (=−μ·Ix·E) from the filter coefficient updater 28 to the imaginary-part filter coefficient Iw at present, thereby producing a new imaginary-part filter coefficient Iw. The imaginary-part filter coefficient Iw is thus updated according to the following expression (2):

Iw←Iw−μ·Ix·E (2)

Thereafter, the filter coefficient holder 32 holds the real-part filter coefficient Rw thus updated in step S5 in a first holder 58 thereof, and also holds the imaginary-part filter coefficient Iw thus updated in step S5 in a second holder 60 thereof.

In step S6, the frequency switcher 34 determines a next target frequency Fc′ based on the target frequency Fc set in step S2. In step S6, the target frequency Fc may be updated (Fc′≠Fc) or may not be updated (Fc′=Fc). A specific process of judging whether the target frequency Fc is to be updated or not, or determining an updating quantity for the target frequency Fc will be described later.

In step S7, the amplitude/phase adjuster 36 generates a canceling signal B by adjusting the amplitude and/or phase of the control signal O input thereto from the adaptive notch filter 24.

The amplitude/phase adjuster 36 includes an amplitude adjuster 62 for adjusting the amplitude of the control signal O with a first adjusting value Gfb as a parameter for adjusting the amplitude, a phase adjuster 64 for adjusting the phase of the control signal O with a second adjusting value θfb as a parameter for adjusting the phase, a first storage unit 66 for storing the first adjusting value Gfb to be supplied to the amplitude adjuster 62, and a second storage unit 68 for storing the second adjusting value θfb to be supplied to the phase adjuster 64. The control signal O is adjusted in amplitude by the amplitude adjuster 62 and in phase by the phase adjuster 64, and then supplied as a canceling signal B to the speaker 18.

In view of the additivity of trigonometric functions, the result obtained by adjusting the amplitude or phase of the control signal O is in agreement with the result obtained by adjusting the amplitude or phase of each of the real-part reference signal Rx and the imaginary-part reference signal Ix and then combining the separately-adjusted signals. Therefore, the amplitude/phase adjuster 36 may acquire the real-part reference signal Rx and the imaginary-part reference signal Ix separately from the reference signal generator 22, adjust the amplitude or phase of the acquired signals separately, and then combine the separately-adjusted signals to generate a canceling signal B.

In response to change of the target frequency Fc of the reference signal X by the frequency switcher 34, the amplitude/phase switcher 38 may change the adjusting value (the first adjusting value Gfb, the second adjusting value θfb) stored in the amplitude/phase adjuster 36 (the first storage unit 66, the second storage unit 68). The changing of the target frequency Fc to the target frequency Fc′ can thus immediately be reflected through the canceling signal B for better control following capability.

In step S8, the speaker 18 outputs canceling vibration noise CS based on the canceling signal B from the amplitude/phase adjuster 36. Steps S1 through S8 are subsequently repeated in given sampling periods Ts to cancel out the vibration noise NS.

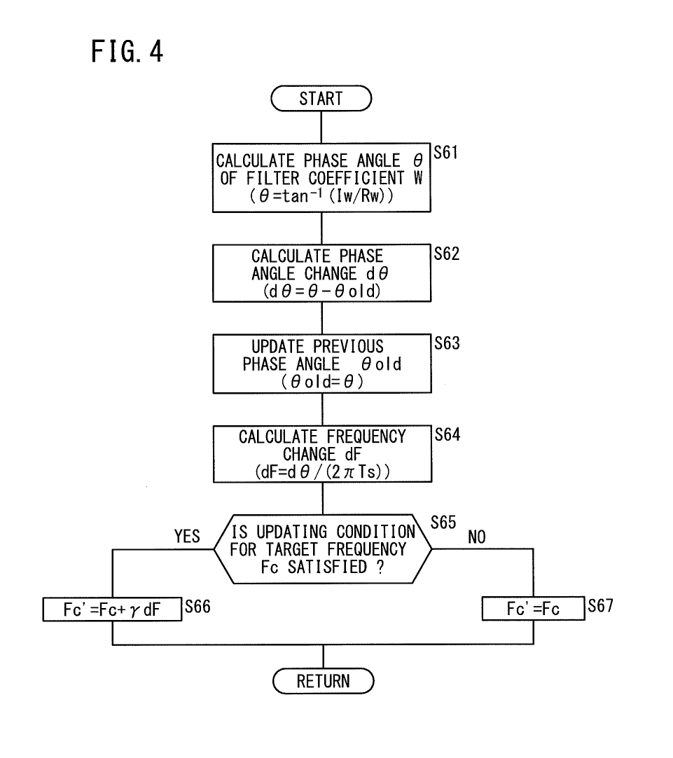

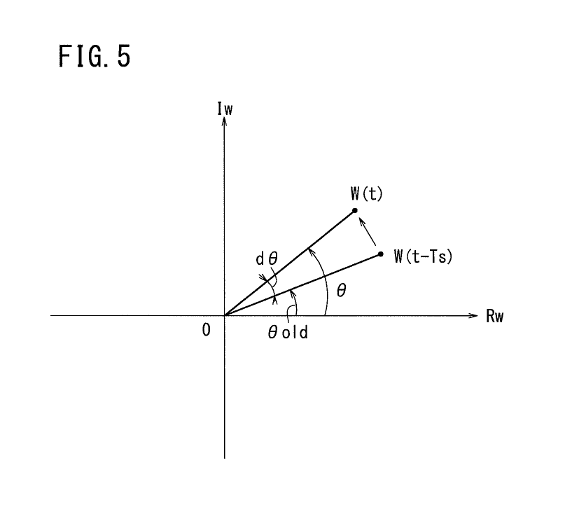

A process of updating the target frequency Fc in step S6, i.e., a specific operation sequence of the frequency switcher 34, will be described below with reference to a flowchart shown in FIG. 4 and a diagram shown in FIG. 5. The process of step S6 may hereinafter be referred to as “frequency switching process”.

In step S61 shown in FIG. 4, the frequency switcher 34 calculates a phase angle θ (0≦θ<2π) in a complex space of a filter coefficient W(t) at present time t of the adaptive notch filter 24. Specifically, the phase angle θ is calculated as θ=tan⁻¹(Iw/Rw) using the filter coefficients (Rw, Iw) at the target frequency Fc.

In step S62, the frequency switcher 34 calculates a phase angle change dθ from the phase angle θ calculated in step S61 and a previously-calculated phase angle (hereinafter referred to as “previous phase angle θold”). Specifically, the phase angle change dθ is calculated according to the following expression (3):

dθ=(θ−θold)mod 2π (3)

The previous phase angle θold corresponds to a phase angle θ of the most recent filter coefficient W(t−Ts). The phase angle change dθ is not limited to the difference between phase angles θ, but may be of any type insofar as it is a parameter representing how much the present phase angle θ has changed from the previous phase angle θold. The phase angle change dθ may be calculated not only using a previously-calculated phase angle, but also using a plurality of recently-calculated phase angles.

In step S63, the frequency switcher 34 substitutes the value of the phase angle θ calculated in step S61 into the previous phase angle θold. The previous phase angle θold is used for the calculation in step S62 in a next cycle.

In step S64, the frequency switcher 34 calculates a frequency change dF from the phase angle change dθ calculated in step S62. Specifically, the frequency change dF is calculated as dF=dθ/(2πTs) where Ts represents a sampling period (unit: s) for inputting the error signal A.

In step S65, the frequency switcher 34 judges whether an updating condition for the target frequency Fc is satisfied or not by judging whether the frequency change dF calculated in step S64 falls within a predetermined range or not. For example, a lower limit threshold value is selected from a range from 0.05 to 0.2 Hz, and an upper limit threshold value is selected from a range from 1 to 3 Hz.

If the frequency change dF satisfies the relationship: Th1≦|dF|≦Th2, then the frequency switcher 34 determines a new target frequency Fc′ according to the updating equation: Fc′=Fc+γdF in step S66. γ is of a positive value (e.g., 0<γ<1) and represents a parameter for adjusting the rate at which the present control changes in response to change of the frequency characteristics of vibration noise, or the like.

If the frequency change dF satisfies the relationship: 0≦|dF|<Th1, then a new target frequency Fc′ is determined as Fc′=Fc, and the frequency switcher 34 does not update the target frequency Fc, but keeps the target frequency Fc in step S67. If the frequency change dF satisfies the relationship: 0≦|dF|<Th1, then the frequency characteristics of the vibration noise NS are regarded as being stable. When the target frequency Fc is not changed, different noise, e.g., an overshoot, is prevented from occurring due to excessive control.

Alternatively, if the relationship: |dF|>Th2 is satisfied, then a new target frequency Fc′ is determined as Fc′=Fc and the frequency switcher 34 does not update the target frequency Fc, but keeps the target frequency Fc in step S67. If the relationship: |dF|>Th2 is satisfied, it is assumed that it is difficult to predict how the vibration noise NS behaves, or a sufficient period of time has not elapsed after the activation of the ANC apparatus 10. When the target frequency Fc is not changed, different noise, e.g., an overshoot, is prevented from occurring due to excessive control.

In this manner, the frequency switcher 34 sequentially determines the target frequency Fc in given sampling periods Ts in step S6.

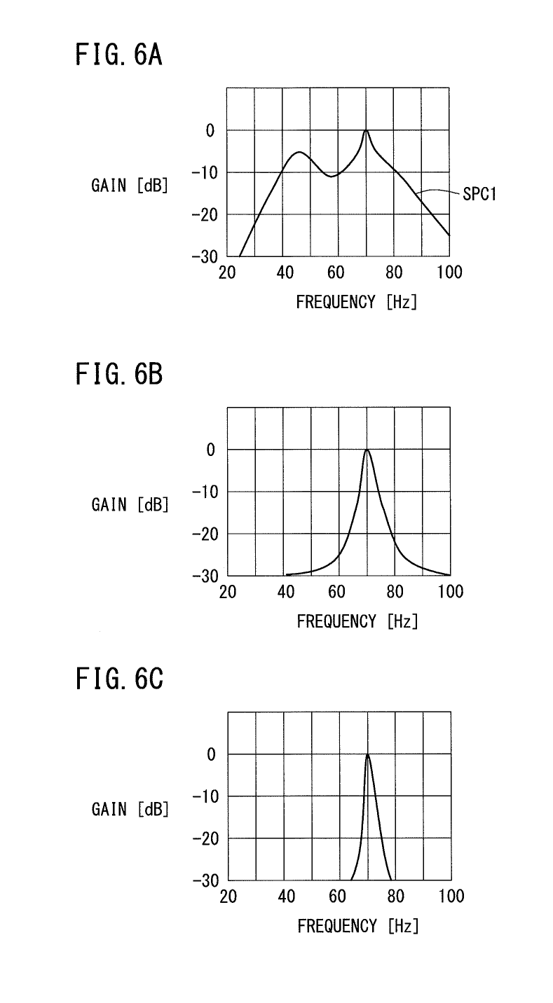

Advantages accruing from the above frequency switching process will be described below with reference to FIGS. 6A through 9C. Each of FIGS. 6A through 9C is a graph horizontal axis of which represents frequencies [Hz] and vertical axis of which represents gains [dB] (logarithmic amplitude).

FIG. 6A is a spectral diagram of an error signal A prior to the execution of the ANC process. A first spectrum SPC1 has a peak in the vicinity of a frequency of 45 Hz and another peak in the vicinity of a frequency of 70 Hz. It is assumed that the ANC process is carried out to suppress the peak, which is maximum in spectral intensity, in the vicinity of the frequency of 70 Hz.

FIG. 6B is a diagram showing the frequency characteristics of the SAN bandpass filter 30 that is suitable for the error signal A shown in FIG. 6A. The frequency setting unit 20 (see FIGS. 1 and 3) sets the target frequency Fc to Fc=70 Hz thereby to provide filter frequency characteristics which has the maximum gain (i.e., minimum signal loss) at the frequency of 70 Hz, as shown in FIG. 6B. It is thus possible to selectively extract a frequency component to be canceled out, from the vibration noise NS input from the microphone 16.

FIG. 6C is a diagram showing the frequency characteristics of the adaptive notch filter 24, which correspond to the frequency characteristics of the SAN bandpass filter 30 shown in FIG. 6B. The frequency characteristics shown in FIG. 6C are substantially in agreement with the sum of the first spectrum SPC1 shown in FIG. 6A and the gain of the SAN bandpass filter 30 shown in FIG. 6B at each frequency.

Resonant noise of the vehicle 11 may have a different tendency due to an interaction between various parts of the suspensions, etc. of the vehicle 11. For example, the resonant frequency may be dynamically changed depending on how the vehicle 11 is traveling.

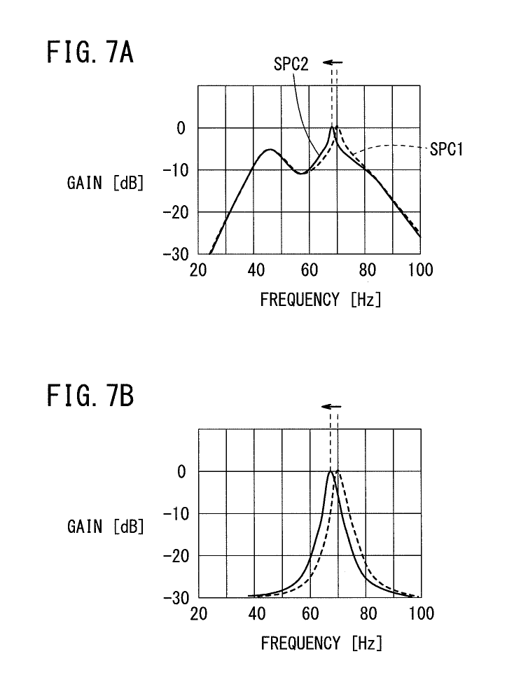

As shown in FIG. 7A, it is assumed that when the vehicle 11 is traveling, the frequency characteristics of the error signal A, i.e., the first spectrum SPC1 indicated by the broken-line curve, are changed, shifting the resonant frequency from 70 Hz to 67 Hz. The changed frequency characteristics will be referred to as a second spectrum SPC2 indicated by the solid-line curve.

FIG. 7B is a diagram showing the frequency characteristics of the SAN bandpass filter 30 that is suitable for the error signal A shown in FIG. 7A. As is the case with the frequency characteristics shown in FIGS. 6A and 6B, it is possible to selectively extract a frequency component to be canceled out from the vibration noise NS input from the microphone 16, by using a filter which has the maximum gain at the peak-amplitude frequency of 67 Hz of the second spectrum SPC2.

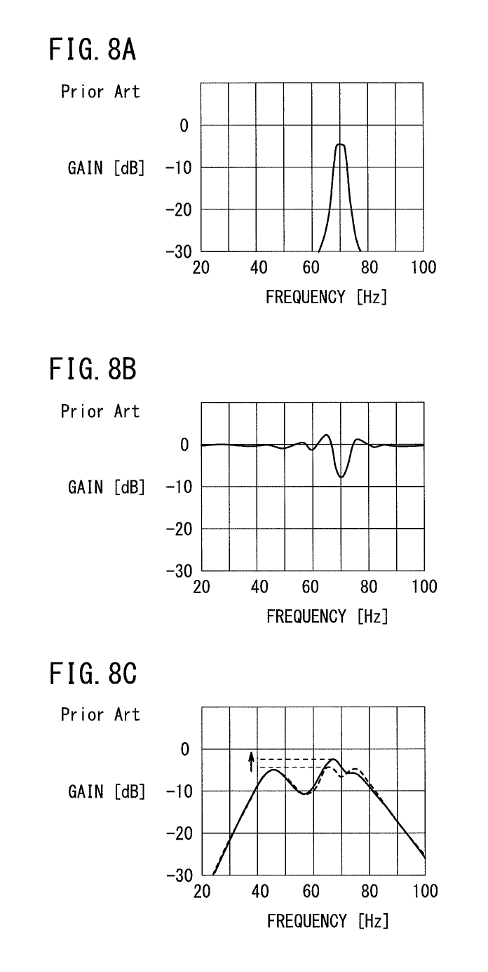

If the above frequency switching process is not carried out, then the SAN bandpass filter 30 remains to have the frequency characteristics shown in FIG. 6B. In this case, as shown in FIG. 8A, the frequency characteristics of the adaptive notch filter 24 have a lower gain in the vicinity of 67 Hz compared with the frequency characteristics shown in FIG. 6C. As a result, the sensitivity function of the ANC apparatus 10 shown in FIG. 8B is obtained, and the error signal A has the spectrum shown in FIG. 8C.

In FIG. 8C, the solid-line characteristic curve represents frequency characteristics obtained after the ANC process has been carried out on the error signal A that has the second spectrum SPC2, and the broken-line characteristic curve represents frequency characteristics obtained after the ANC process has been carried out on the error signal A that has the first spectrum SPC1. Therefore, when the resonant frequency of the vibration noise NS is shifted slightly off the target frequency Fc, the vibration noise NS cannot sufficiently be canceled out in the vicinity of the resonant frequency.

Compared to this, with the ANC apparatus 10 according to the present invention, the active vibration noise controller 14 dynamically changes the passband of the SAN bandpass filter 30 in response to a shift in the resonant frequency. Specifically, the frequency switcher 34 calculates a frequency change dF (=−3 Hz), and thereafter changes the target frequency Fc from 70 Hz to 67 Hz. The frequency characteristics of the SAN bandpass filter 30 now change from the broken-line characteristic curve to the solid-line characteristic curve in FIG. 7B.

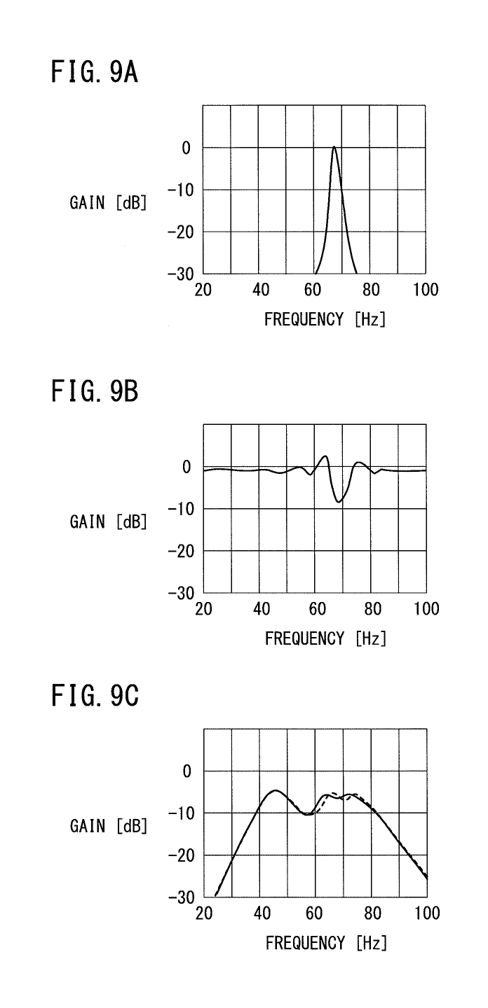

When the above frequency switching process is carried out, as shown in FIG. 9A, the frequency characteristics of the adaptive notch filter 24 have a greater gain in the vicinity of 67 Hz compared with the frequency characteristics shown in FIG. 8A. As a result, the sensitivity function of the ANC apparatus 10 shown in FIG. 9B is obtained, and the error signal A has the spectrum shown in FIG. 9C.

In FIG. 9C, the solid-line characteristic curve represents frequency characteristics obtained after the ANC process has been carried out on the error signal A that has the second spectrum SPC2, and the broken-line characteristic curve represents frequency characteristics obtained after the ANC process has been carried out on the error signal A that has the first spectrum SPC1. Therefore, even when the resonant frequency of the vibration noise NS is shifted, the vibration noise NS is canceled out substantially equally before and after the resonant frequency is shifted.

As described above, the ANC apparatus 10 includes the frequency switcher 34 which calculates a phase angle change dθ between the phase angle θ in the complex space of the filter coefficient W (Rw, Iw) of the adaptive notch filter 24, and the previous phase angle θold calculated when the filter coefficient is updated previously, and changes the target frequency Fc of the reference signal X depending on the calculated phase angle change dθ. Therefore, a change in the phase angle θ in the complex space of the filter coefficient W can be monitored sequentially, and the tendency of a change in the frequency characteristics can simply and accurately be grasped from the phase angle change dθ. Consequently, the vibration noise NS with changing frequency characteristics can be canceled out in response to the change in the frequency characteristics.

Although a certain preferred embodiment of the present invention has been shown and described in detail, it should be understood that various changes and modifications may be made therein without departing from the scope of the appended claims.

What is claimed is:

1. An active vibration noise control apparatus comprising:
a vibration noise canceller for outputting canceling vibration noise based on a canceling signal to cancel out vibration noise;
an error signal detector for detecting residual vibration noise due to an interference between the vibration noise and the canceling vibration noise as an error signal; and
an active vibration noise controller for generating the canceling signal in response to the error signal input thereto;
wherein the active vibration noise controller comprises:
a reference signal generator for generating a reference signal having a frequency;
an adaptive notch filter, which has a filter coefficient defined in a complex space, for outputting a control signal for use in generating the canceling signal in response to the reference signal input thereto;
an amplitude/phase adjuster for storing therein an amplitude or phase adjusting value depending on the frequency of the reference signal, and generating the canceling signal by adjusting an amplitude or phase of the control signal with the amplitude or phase adjusting value;
a corrective error signal generator for generating a corrective error signal by subtracting the control signal from the error signal;
a filter coefficient updater for sequentially updating the filter coefficient so as to minimize the corrective error signal based on the reference signal and the corrective error signal; and
a frequency switcher for calculating a phase angle change between a phase angle in the complex space of the filter coefficient and a phase angle calculated when the filter coefficient is updated previously, and changing the frequency of the reference signal depending on the calculated phase angle change.

2. The active vibration noise control apparatus according to claim 1, wherein the frequency switcher calculates a change in the frequency based on a sampling period of the error signal and the phase angle change, and maintains the frequency of the reference signal if the change in the frequency is lower than a lower limit threshold value.

3. The active vibration noise control apparatus according to claim 2, wherein the frequency switcher maintains the frequency of the reference signal if the change in the frequency is higher than an upper limit threshold value which is greater than the lower limit threshold value.

4. The active vibration noise control apparatus according to claim 1, further comprising:
an amplitude/phase switcher for changing the amplitude or phase adjusting value which is stored in the amplitude/phase adjuster, in response to change of the frequency of the reference signal by the frequency switcher.
